(19) United States
(12) Patent Application Publication
(10) Pub. No.: US 2025/0007465 A1
(43) Pub. Date: Jan. 2, 2025

(54) COMPACT MATCHING NETWORKS FOR GALLIUM NITRIDE DOHERTY POWER AMPLIFIER IN A SMALL FORM-FACTOR PACKAGE

(71) Applicants: City University of Hong Kong, Kowloon (HK); The Education University of Hong Kong, New Territories (HK)

(72) Inventors: Wai Yin Mung, New Territories (HK); Wing Lun NG, Kowloon (HK); Wing Shing Chan, Kowloon (HK)

(21) Appl. No.: 18/341,934

(22) Filed: Jun. 27, 2023

(51) Int. Cl. H03F 1/02; H03F 1/56; H03F 3/21

(52) U.S. Cl. CPC H03F 1/0288; H03F 1/565; H03F 3/211; H03F 2200/387

(57) ABSTRACT

A sub-1-mm² die area is presented. This small die with the compact source network (CSN) and compact load network (CLN) can be fully packaged in a small form factor. Previous solutions have integrated all components into the die with complicated matching and bias networks, resulting in a large and expensive die area. Innovative component merging and compact bond-wire matching in the CSN and CLN have substantially reduced the die size for future massive multiple-input-multiple-output (MIMO) small cells. This proposed DPA was designed and fabricated using a commercial 150-nm GaN/silicon carbide (SiC) high electron mobility transistor (HEMT) process to validate architecture and design methodologies.

### FIELD OF INVENTION

This invention relates to power amplifiers and in particular to Doherty power amplifiers (DPAs) used in RF (Radio Frequency)/Microwave/Wireless systems.

### BACKGROUND OF INVENTION

In recent years, gallium nitride (GaN) on silicon carbide (SiC) process has provided the best performance with regards to thermal conductivity. Therefore, different power amplifier (PA) techniques have been proposed using the GaN process for 5G applications [1], [2]. However, these processes have their shortcomings as a result of using nonmainstream silicon processes, which also result in higher costs. To lower die costs and allow a smaller footprint for future massive multiple-input-multiple-output (MIMO) small cells, the die size of GaN PAs has to be reduced. This GaN technology benefits Doherty PAS (DPAs) since using fully integrated lumped elements within the die for DPAs [3], [4], [5], [6], [7], [8] results in reduced size advantages.

### REFERENCES

Each of the following references (and associated appendices and/or supplements) is expressly incorporated herein by reference in its entirety:
[1] G. R. Nikandish, R. B. Staszewski, and A. Zhu, “A fully integrated reconfigurable multimode class-F2,3GaN power amplifier,” IEEE Solid-State Circuits Lett., vol. 3, pp. 270-273, 2020.
[2] G. R. Nikandish, R. B. Staszewski, and A. Zhu, “Broadband fully integrated GaN power amplifier with embedded minimum inductor bandpass filter and AM-PM compensation,” IEEE Solid-State Circuits Lett., vol. 2, pp. 159-162, 2019.
[3] H. Lee et al., “Highly efficient fully integrated GaN-HEMT Doherty power amplifier based on compact load network,” IEEE Trans. Microw. Theory Techn., vol. 65, no. 12, pp. 5203-5211 December 2017.
[4] S.-H. Li, S. S. H. Hsu, J. Zhang, and K.-C. Huang, “Design of a compact GaN MMIC Doherty power amplifier and system level analysis with X-parameters for 5G communications,” IEEE Trans. Microw. Theory Techn., vol. 66, no. 12, pp. 5676-5684 December 2018.
[5] G. Lv, W. Chen, X. Liu, F. M. Ghannouchi, and Z. Feng, “A fully integrated C-band GaN MMIC Doherty power amplifier with high efficiency and compact size for 5G application,” IEEE Access, vol. 7, pp. 71665-71674, 2019.
[6] G. Nikandish, R. B. Staszewski, and A. Zhu, “Bandwidth enhancement of GaN MMIC Doherty power amplifiers using broadband transformer-based load modulation network,” IEEE Access, vol. 7, pp. 119844-119855, 2019.
[7] G. Lv, W. Chen, Y. Zhang, N. Chen, F. M. Ghannouchi, and Z. Feng, “A highly linear GaN MMIC Doherty power amplifier based on phase mismatch induced AM-PM compensation,” IEEE Trans. Microw. Theory Techn., vol. 65, no. 12, pp. 1334-1348 February 2022.
[8] J. Pang et al., “Broadband GaN MMIC Doherty power amplifier using continuous-mode combining for 5G sub-6 GHz applications,” IEEE J. Solid-State Circuits, vol. 57, no. 7, pp. 2143-2154 July 2022.
[9] S. W. Y. Mung and W. S. Chan, “Compact tunable lumped-element Wilkinson power divider with high isolation,” Microw. Opt. Technol. Lett., vol. 53, no. 2, pp. 288-290, February 2011.
[10] C.-H. Li, C.-L. Ko, C.-N. Kuo, M.-C. Kuo, and D.-C. Chang, “A low-cost DC-to-84-GHz broadband bondwire interconnect for SoP heterogeneous system integration,” IEEE Trans. Microw. Theory Techn., vol. 61, no. 12, pp. 4345-4352 December 2013.

### SUMMARY OF INVENTION

Accordingly, the invention in one aspect provides a Doherty power amplifier which includes an input, an output, a main power amplification device connected between the input and the output, an auxiliary power amplification device connected between the input and the output, an output matching network, and an impedance transformer. The auxiliary power amplification device is arranged in parallel with the main power amplification device. The output matching network is connected between the output, and the main and auxiliary power amplification devices. The impedance transformer is connected between the output matching network and the output. A first part of the output matching network is merged with a first part of the impedance transformer.

In some embodiments, both the output matching network and the impedance transformer contain high-pass x-type lumped networks. The first part of the output matching network and the first part of the impedance transformer contain inductors that are merged.

In some embodiments, the inductors of the first part of the output matching network and the first part of the impedance transformer, which are merged, are implemented as a bondwire.

In some embodiments, the Doherty power amplifier further contains a power splitter and an input offset line that are connected between the input, and the main and auxiliary power amplification device. A first part of the input offset line is merged with a first part of the power splitter.

In some embodiments, both the input offset line and the power splitter contain high-pass x-type lumped networks. The first part of the input offset line and the first part of the power splitter contain inductors that are merged.

In some embodiments, the inductors of the first part of the input offset line and the first part of the power splitter, which are merged, are implemented as a bondwire.

In some embodiments, the power splitter further contains a second part that contains inductors which are merged within the power splitter.

In some embodiments, the Doherty power amplifier further includes an input matching network that is connected between the input, and the main and auxiliary power amplification devices. The input matching network includes shunt inductors which are implemented using bondwires.

In some embodiments, the input matching network is merged with an input bias network.

In some embodiments, the output matching network is merged with an output bias network.

In some embodiments, the impedance transformer further contains a second part that contains an inductor implemented using a bondwire.

In some embodiments, the impedance transformer is a λ/4 impedance transformer.

In some embodiments, the first part of the output matching network is further merged with a first part of an output offset line.

In some embodiments, a second part of the output matching network is merged with a second part of the output offset line.

Embodiments of the invention thus provide GaN DPAs with a compact source network (CSN) and a compact load network (CLN) to create a small form-factor package. In some implementations the overall die size of the DPA may be reduced to sub-1-mm², without degradation in performance compared to other conventional DPAs.

### BRIEF DESCRIPTION OF FIGURES

The foregoing and further features of the present invention will be apparent from the following description of embodiments which are provided by way of example only in connection with the accompanying figures, of which:

FIG. 1 is a high-level schematic diagram of a DPA according to one embodiment of the invention.

FIG. 2 shows in lumped circuits the input matching network (IMN), the output matching network (OMN), and power cell in main and peaking PAs in the DPA of FIG. 1.

FIG. 3 illustrates in lumped circuits the power splitter and the λ/4 input offset line in the CSN of the DPA of FIG. 1, as well as merging of certain inductors.

FIG. 4 illustrates in lumped circuits the CLN and IMN around the power cells, in the DPA of FIG. 1, as well as merging of certain inductors.

FIG. 5 illustrates a cross-section of a bondwire used as inductance according to an embodiment of the invention.

FIG. 6 illustrates a complete circuit of a DPA that is made according to the schematic in FIG. 1, including bondwire implementations for some inductors, according to an embodiment of the invention.

FIG. 7a is a die photograph of a sample DPA manufactured according to the circuit in FIG. 6.

FIG. 7b is a photo of an evaluation board carrying the die in FIG. 7a which is built for measuring characteristics of the die.

FIG. 8 includes enlarged views of the die and bondwires around the die on the evaluation board of FIG. 7b.

FIG. 9 shows simulated and measured (using the sample shown in FIG. 7b)S-parameters of the DPA.

FIG. 10 shows a large-signal measurement setup of the evaluation board of FIG. 7b.

FIG. 11a illustrates measured gain of the DPA in FIG. 7a versus output power versus different gate bias voltages for the peaking PA at 4.3 GHZ.

FIG. 11b illustrates measured drain efficiency (DE) of the DPA in FIG. 7a versus output power versus different gate bias voltages for the peaking PA at 4.3 GHZ.

FIG. 12a illustrates measured gain of the DPA in FIG. 7a versus output power versus different frequencies.

FIG. 12b illustrates measured DE of the DPA in FIG. 7a versus output power versus different frequencies.

### DETAILED DESCRIPTION

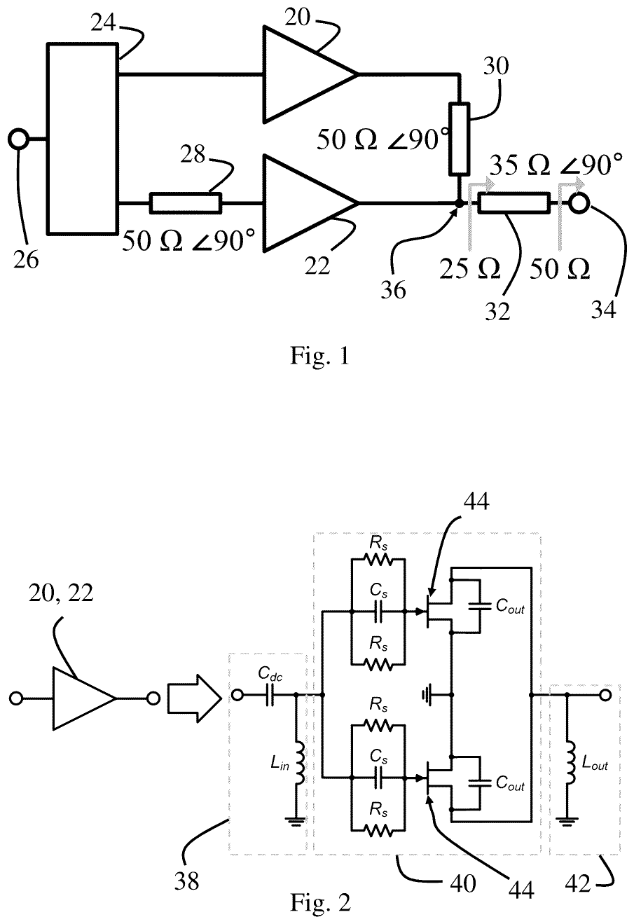

FIG. 1 shows a high-level schematic diagram of a GaN Doherty power amplifier according to a first embodiment of the invention. It should be noted that there is no specific circuit implementation illustrated in FIG. 1, because there are more than one possible implementations for the DPA in FIG. 1, an example of which will be described in detail later. There are two parallel amplifier paths in the DPA, and two power amplification devices are located respectively on the two paths, as understood by those skilled in the art. In particular, in a carrier path there is a main power amplification device 20 that operates in class B mode, and in a peaking path there is an auxiliary power amplification device 22 that operates in class C mode. The two power amplification devices 20, 22 are each illustrated in FIG. 1 using a single amplifier logo, but skilled persons will understand that actual circuits of the power amplification devices may include amplifier elements (e.g., transistors), input impedance matching circuits, input biasing networks, output impedance matching circuits, output biasing networks, etc., all of which are not shown in FIG. 1.

The DPA in FIG. 1 has an input 26 (for receiving RF signals) and an output 34, where the main and auxiliary power amplification devices 20, 22 are connected between the input 26 and the output 34. In addition, a power splitter 24 is connected between the input 26, and the main and auxiliary power amplification devices 20, 22. The power splitter 24 is arranged to receive an RF signal from the input 26 and split the RF signal into at least a signal to be transmitted to the main power amplification device 20, and a signal to be transmitted to the auxiliary power amplification device 22. While the power splitter 24 is shown in FIG. 1 to be directly connected to the main power amplification device 20, there is further an input offset line 28 connected between the power splitter 24 and the auxiliary power amplification device 22. The input offset line 28 is a λ/4 input offset line (50Ω∠) 90°, and is used for phase compensation of the auxiliary power amplification device 22 with the main power amplification device 20. Both the power splitter 24 and the input offset line 28 are part of a CSN of the DPA.

At the output sides of the main and auxiliary power amplification devices 20, 22, there is a summing node 36 which as understood by skilled persons is at the location where a main amplifier current (not shown) from the main power amplification device 20 and an auxiliary amplifier current (not shown) from the auxiliary power amplification device 22 are combined. Between the summing node 36 and the output 34, there is connected an impedance transformer 32 which transfers an impedance (e.g., 25Ω) seen at the summing node 36 to a desired output impedance seen at the output 34 (e.g., 50Ω). The impedance transformer 32 as shown in FIG. 1 is a λ/4 impedance transformer (35Ω∠90°). In addition, while the auxiliary power amplification device 22 is shown to be directly connected to the summing node 36, there is an output offset line 30 connected between the main power amplification device 20 and the summing node 36. The output offset line 30 as shown in FIG. 1 is a λ/4 output offset line (50Ω∠90°). Both the output offset line 30 and the impedance transformer 32 are part of a CLN of the DPA

Turning to FIG. 2, in which the internal structures of the main and auxiliary power amplification devices 20, 22 are illustrated. It should be noted that the main and auxiliary power amplification devices 20, 22 share identical circuit structures as shown in FIG. 2, and each includes an input matching network (IMN) 38, an output matching network (OMN) 42, and a power cell 40 connected between the IMN 38 and the OMN 42. The IMN 38 is part of the CSN that is mentioned above, and the OMN 42 is part of the CLN that is mentioned above. Notably, the IMN 38 and the OMN 42 are merged respectively into input and output bias networks (not shown in FIG. 2, and which also have abbreviated names of IMN and OMN) in each of the main and auxiliary power amplification device 20, 22. In the IMN 38, there is a shunt inductor Lᵢₙ which at its one end is grounded, and at its another end is connected to a second end of an input capacitor (′dc. A first end of the input capacitor C_{dc} is connected to an input of the IMN 38 (which is also the input of the main power amplification device 20/auxiliary power amplification device 22). Thus, for the main power amplification device 20 the first end of the input capacitor C_{dc} is connected to the power splitter 24, and for the auxiliary power amplification device 22 the first end of the input capacitor C_{dc} is connected to the input offset line 28. The input capacitor C_{dc} is used for DC blocking and can be used for input matching if needed.

An output of the IMN 38 which is at the second end of the input capacitor C_{dc} is connected to the power cell 40. The power cell 40 as shown in FIG. 2 has a symmetrical structure, as there are two parallel paths each of which contains a transistor 44. At a gate of each transistor 44 there is connected a RC stabilization network that includes two resistors Rₛ and a capacitor Cₛ, the three of which being configured in parallel. The two resistors Rₛ are used in the RC stabilization networks for full symmetry. In addition, there is a capacitor Cₒᵤₜ connected between a drain and a source of each transistor 44. The source of each transistor 44 is further grounded, while the drain of each transistor 44 is further connected to the OMN 42, and in particular to a first end of a shunt inductor Lₒᵤₜ in the OMN 42. A second end of the shunt inductor Low is grounded. The first end of the shunt inductor Lₒᵤₜ is also the output of the main power amplification device 20/auxiliary power amplification device 22. The capacitors Cₒᵤₜ provide the ground for the shunt inductor Lₒᵤₜ. and also can be used for output matching if needed.

In one exemplary implementation, the DPA as shown in FIGS. 1 and 2 is designed using a 150-nm power GaN/SiC high electron mobility transistor (HEMT) process from WIN Semiconductors. Both the main and auxiliary power amplification devices 20, 22 have a drain supply voltage V_{d} of 28V. The desired maximum power delivered from the DPA is 39 dBm (around 8 W), so Zₒₚₜ=50Ω and Z_{o,output}=35Ω, which can be found from Eq. (1)

$${P}_{out} = {( \frac{{V}_{d}}{\sqrt{2}} )}^{2} / {Z}_{opt} \qquad Eq . ( 1 )$$

and the λ/4 impedance transformer equation, Zₒ=√Zᵢₙ Z_{L}, respectively. Both Z_{T} and Z_{o,input} then become equal to 50Ω. To achieve a desired maximum power, all the transistors 44 are 6×75 μm in size.

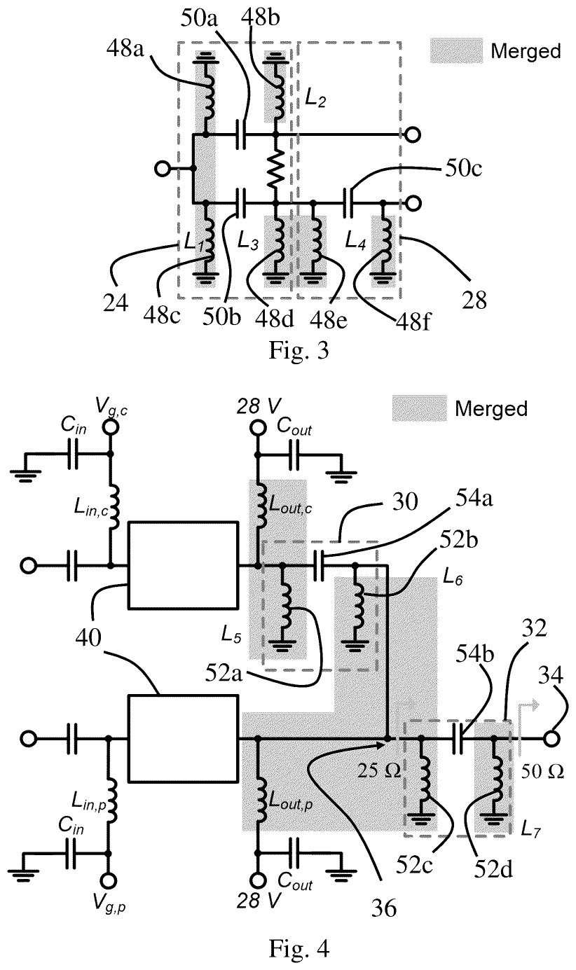

Turning to FIGS. 3-4, the structures of the CSN and CLN in the DPA as shown in FIGS. 1 and 2 can be simplified at least by absorbing the bias network with the matching network. The simplification could be achieved for example by merging one or more inductors in the various circuit blocks shown in FIGS. 1-2. To begin with, each of the input offset line 28 and the output offset line 30 in FIG. 1 can be realized using high-pass x-type lumped networks, which are found by

$${L}_{pi} = \frac{\sqrt{2} {Z}_{o}}{ω} \sqrt{\frac{1 - cos θ}{1 + cos θ}} \qquad Eq . ( 2 )$$

$${C}_{pi} = \frac{1}{\sqrt{2} {Z}_{o} ω sin θ} \qquad Eq . ( 3 )$$

wherein Lₚᵢ and Cₚᵢ are the inductance and capacitance used in this network, respectively.

FIG. 3 shows both the power splitter 24 and the input offset line 28 of the CSN, both realized using high-pass π-type lumped networks. The power splitter 24 is a conventional Wilkinson power divider realized using lumped elements [9]. As shown in FIG. 2, there are two λ/4 transmission lines in the power splitter 24, the first of which includes inductors 48a-48b and a capacitor 50a connected between the inductors 48a-48b, and the second of which includes inductors 48c-48d and a capacitor 50b connected between the inductors 48c-48d. Similarly, the input offset line 28 includes inductors 48e-48f and a capacitor 50c connected between the inductors 48e-48f. As such, there are in total six inductors 48a-48f in the power splitter 24 and the input offset line 28, which can be reduced to four inductors L₁, L₂, L₃, and L₄ by merging with adjacent shunt inductors. In particular, inductors 48a and 48c as a first part of the power splitter 24 are merged into the inductor L₁. Inductor 48d as a second part of the power splitter 24 and inductor 48e as a first part of the input offset line 28 are merged into the inductor L₃. Inductor 48b as a third part of the power splitter 24 becomes inductor L₂. Inductor 48f as a second part of the input offset line 28 becomes inductor L₄. Since the power splitter 24 and the input offset line 28 are passive components that are reliable and accurate in the simulation, on-chip inductors were used for L₁, L₂, L₃, and L₄.

FIG. 4 shows the integrated input bias and matching networks, and the power cells 40 respectively of the main and auxiliary power amplification devices 20, 22, as well as the CLN. For each power cell 40, the previously mentioned shunt inductor Lᵢₙ (which is labeled as L_{in, c} on the carrier path, and L_{in, p} on the peaking path) and input capacitor C_{dc} are in the positions as shown in FIG. 2, but one end of the shunt inductor Lᵢₙ is now illustrated to be connected to a capacitor Cᵢₙ and a voltage source V_{g} (which is labeled as V_{g, c} on the carrier path, and V_{g, p} on the peaking path). Cᵢₙ at V_{g} provides the AC ground for L_{in,c} and L_{in,p}. but I'm can also be used for input matching if needed. The same power cells 40 are used in both carrier and peaking PAs but they are driven (respectively by V_{g,c} and V_{g,p}) at different classes, and in particular the carrier PA is biased in Class B, while the peaking PA is biased in Class C. Therefore, the PAs will have different parasitic elements, such as different Cₛ as shown in FIG. 2.

The output offset line 30 and the impedance transformer 32 in FIG. 1 are also realized in FIG. 4 using high-pass π-type lumped networks. For each power cell 40, the previously mentioned shunt inductor Lₒᵤₜ (which is labeled as L_{out, c} on the carrier path, and L_{out, p} on the peaking path) are in the positions as shown in FIG. 2, but the inductor L_{out, c} on the carrier path is shown in FIG. 4 to be connected to the output offset line 30. In particular, the output offset line 30 as implemented by lumped circuits contains two inductors 52a-52b which are both grounded, and a capacitor 54a connected between the inductors 52a-52b. Inductor L_{out, c} connects to the inductor 52a, and the inductor 52b connects to the summing node 36. On the other end, the inductor L_{out, p} directly connects to the summing node 36. The impedance transformer 32 as implemented by lumped circuits also contains two inductors 52c-52d which are both grounded, and a capacitor 54b connected between the inductors 52c-52d. The inductor 52c connects to the summing node 36, and the inductor 52d connects to the output 34 of the DPA.

In the CLN as shown in FIG. 4, there are thus six inductors, which can be reduced to three inductors L₅, L₆, and L₇ by merging with adjacent shunt inductors. In particular, inductors L_{out, c} of the output biasing network on the carrier path, and the inductor 52a as a first part of the output offset line 30 are merged into the inductor L₅. Inductor 52b as a second part of the output offset line 30, inductors L_{out, p} of the output biasing network on the peaking path, and inductor 52c as a first part of the impedance transformer 32, are merged into the inductor L₆. Inductor 52d as a second part of the impedance transformer 32 becomes inductor L₇. Inductor 48f as a second part of the input offset line 28 becomes inductor L₄.

One can see that in FIGS. 3-4, since the input and output bias networks are merged with IMN 38 and OMN 42 respectively, the four shunt inductors (L_{in,c}, L_{in,p}, L_{out,c}, and L_{out,p}) at the input and output of the power cells 40 become the actual IMNs and OMNs, respectively. These are also used for DC supplies for gate voltage (V_{g}) and V_{d.} L_{in,c} and L_{in,p} are used for input matching. L_{out,c} and L_{out,p} are used as Lₒᵤₜ shown in FIG. 2, for output parallel resonance matching with parasitic output capacitors (C_{ds}, which is not shown in the figures) in the power cells 40. Different L_{out,c} and L_{out,p} are used because both carrier and peaking PAs are biased differently. Cₒᵤₜ at_V_{ds} provides the ground for the L_{out,c} and L_{out,p}, and can also be used for output matching if needed. Cₒᵤₜ provides the AC ground for L₅, and L₆. Since high power will be delivered at the DPA output, which passes through the CLN, in one exemplary implementation of the circuit in FIGS. 3 and 4, bondwires are used to replace the merged shunt inductors (L₅, L₆, and L₇) to achieve low loss.

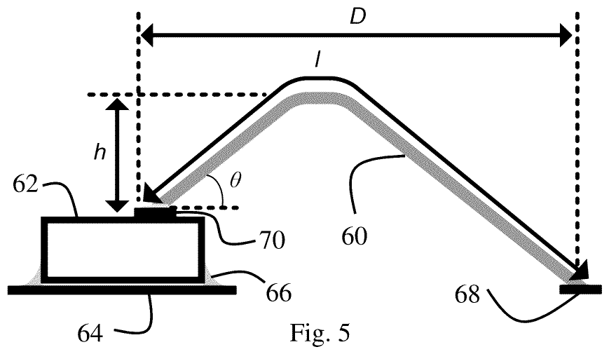

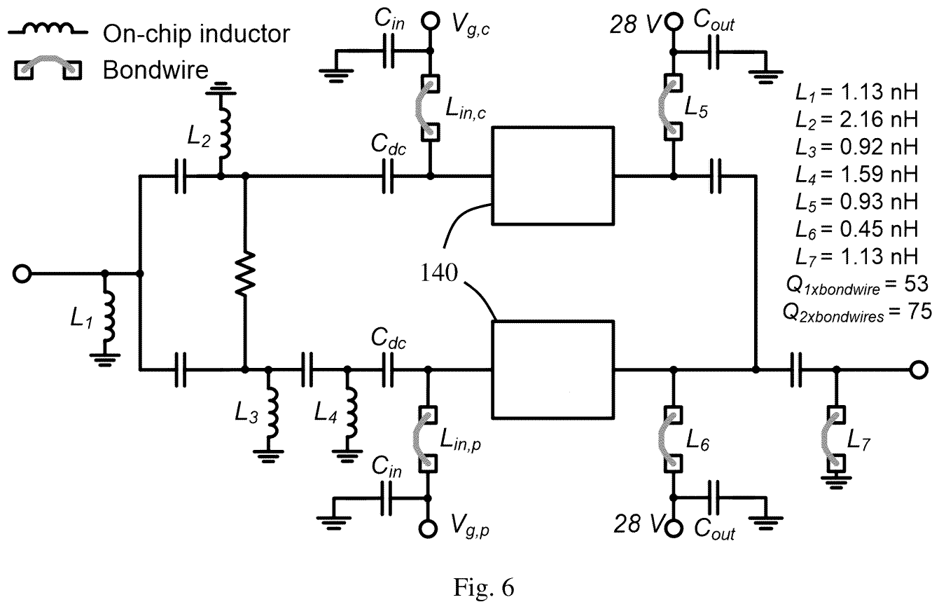

FIG. 5 shows the cross section of a type of exemplary bondwire 60 that may be used to implement the merged shunt inductors in the CSN and CLN as shown in FIGS. 3-4. The effective inductance (L_{b}) of the bondwire 60 can be found by

$${L}_{b} = {L}_{self} - {L}_{m , image} \qquad Eq . ( 4 )$$

where L_{self} is the bondwire equivalent inductance, which depends on its diameter, length (l), and the number of parallel bondwires [10]. l depends on the angle (θ), loop height (h), and distance (D). Since the IMNs (L_{in,c} and L_{in,p}) and OMNs (L_{out,c} and L_{out,c}) are realized using bondwires, there is tuning flexibility that can be used to optimize DPA performance. Multiple in-parallel bondwires are used due to the current passing through the bondwires and the required high-quality factor. L_{m,image} is the mutual inductance between a bondwire and its image [10].

As shown in FIG. 5, the die 62 is attached to the large ground pad 64 of the package using conductive die attach adhesive 66, which has good thermal conductivity. The first bond location is on the die while the second bond location is on the lead frame 68 of the package. The lead frames 68 at the second bond can be connected to the die attach paddle 70 (ground) or the pinouts of the package. This bondwire replacement can reduce the on-chip inductors in DPA for size reduction. This also takes advantage of V_{g} and V_{dc} DC supplies since bondwires are normally required for connecting to the pinouts in the final package.

FIG. 6 shows the complete schematic diagram of a DPA circuit with the CSN and CLN using a 150-nm power GaN/SiC HEMT process from WIN Semiconductors. The DPA circuit is based on the lumped circuit topography shown in FIGS. 3-4, and utilizes bondwires. The power cell 140 used in FIG. 6 is the same as that in FIG. 2. Two transistors, each with a size of 6×75 μm, and an outside back via were chosen for every power cell 140. The carrier PA is biased at V_{g}=−1.9 V under Class-B condition while the peaking PA is biased at V_{g}=−5 V under Class-C condition. Both drain supplies use 28 V. PathWave Advanced Design System (ADS) Software from Keysight is used for circuit model and electromagnetic (EM) simulations. High-pass π-type lumped networks are used with adjacent inductors merged into one in both the CSN and CLN similar to what are described for FIGS. 3-4.

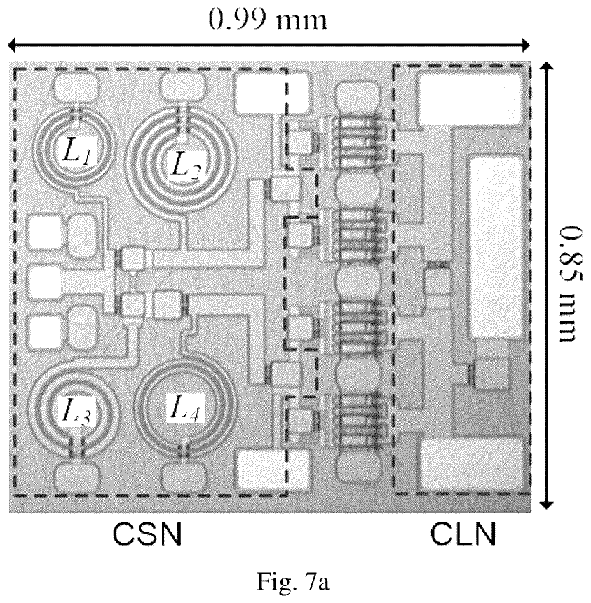

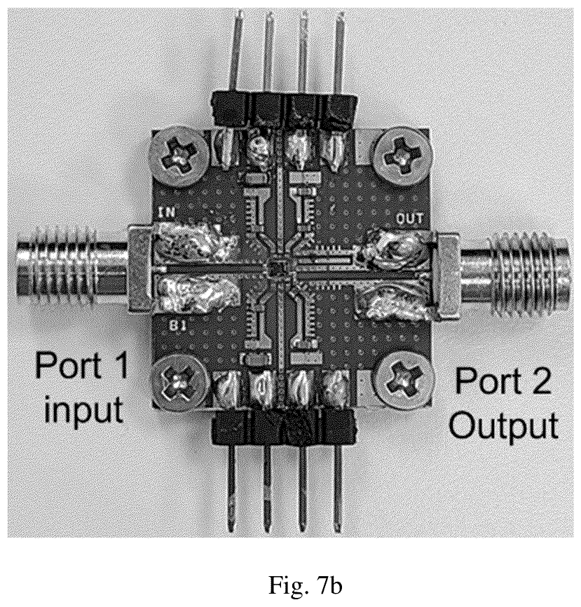

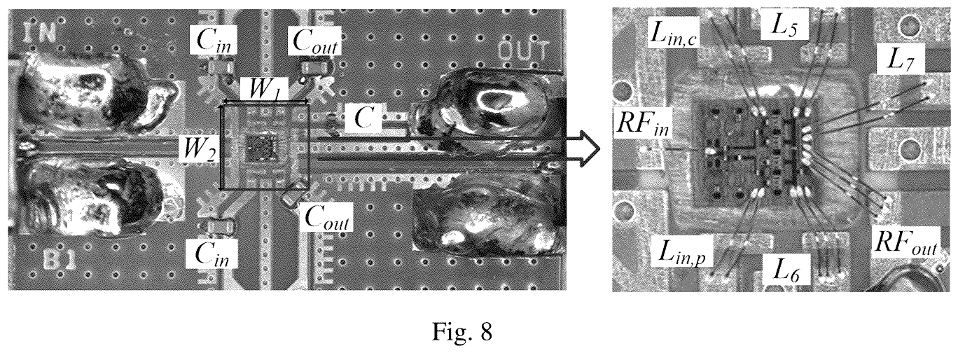

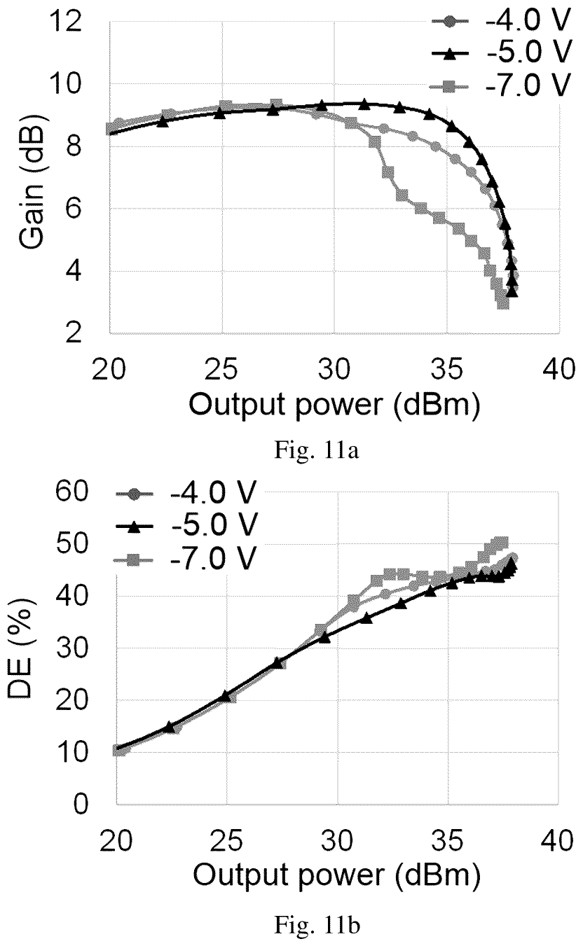

FIG. 7a shows a die photograph of a fabricated sample DPA that is built according to the circuit in FIG. 6. The DPA die area is 0.99×0.85 mm², which is mounted onto an evaluation board with RF connectors for measurement, as shown in FIG. 7b. FIG. 8 shows the fabricated die assembled with bondwires onto the evaluation board. Aluminum bondwires with the same profile as in FIG. 5 were used in both the IMN and CLN with h=150 μm (used for all bondwires). Different D values are used for inductance tuning. One bondwire (RFᵢₙ) is used for input and two bondwires (RFₒᵤₜ) are used for the output for measurement. Cᵢₙ, Cₒᵤₜ, and C uses 1 nF capacitors for RF short and DC decoupling but C can be removed in the final package, which is not shown in FIG. 6. FIG. 8 shows that the size of the final package is 2.7×2.4 (W₁×W₂) mm². L_{in,c} and L_{in,p} for the IMN in FIG. 11 can be used to optimize the input return loss and achieve better gain while L₅ and L₆ are used to optimize the large-signal performance, since L_{out,c} and L_{out,p} OMNs are merged into L₅ and L₆. I for L_{in,c}, L_{in,p}, L₅, and L₆ can be further reduced by using higher h or other loop profiles, such as a square loop, to increase L shown in FIG. 5.

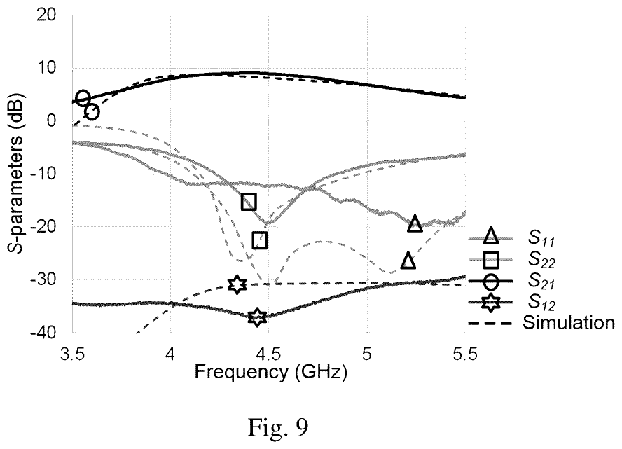

Small-signal performance of the fabricated sample DPA was measured using a Rohde & Schwarz (R&S) ZVB8 vector network analyzer. Simulated and measured small-signal S-parameters of the fabricated DPA are also shown in FIG. 9 for comparison. Simulated and measured small-signal return losses (S₁₁ and S₂₂) and gain (S₂₁) ranged from 3.5 to 5.5 GHz with more 30 dB isolation (S₁₂). The small-signal return losses are more than 10 dB while the gain is larger than 8 dB at the target frequency range of 4.2 to 4.6 GHz. Both simulation and measurement curves exhibit the same trend. The small drift in frequency may be due to mutual coupling between the bondwires and traces on the board, which are not included in the ADS bondwire circuit model.

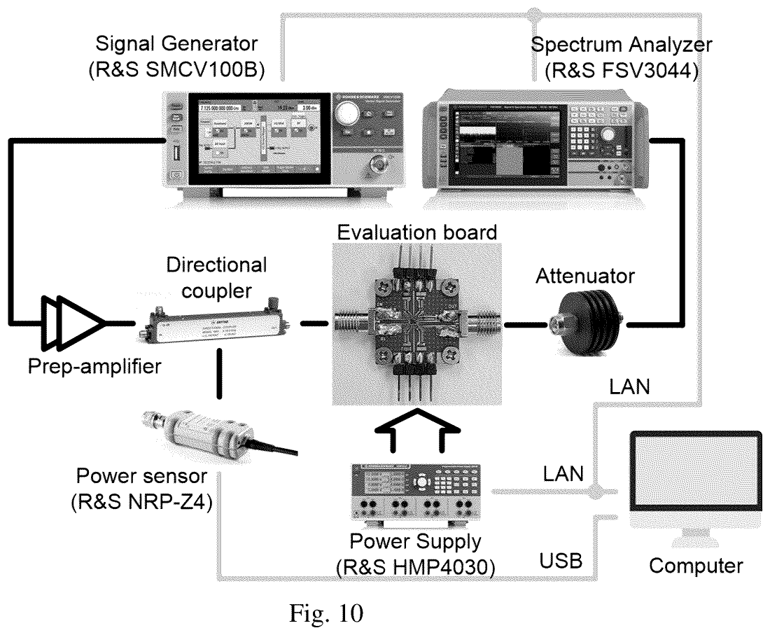

FIG. 10 shows the large-signal measurement setup under single-tone continuous-wave excitation. The output power of the signal generator is not sufficient to determine the desired Pₛₐₜ, so a pre-amplifier with 4-W output power was used. A directional coupler and power sensor at the input is used to measure the input power delivered to the DPA for gain calculation. A simple automated test equipment program was developed to carry the large-signal measurement under different output powers and frequencies for current and input power measurement for the gain and drain efficiency (DE) calculation.

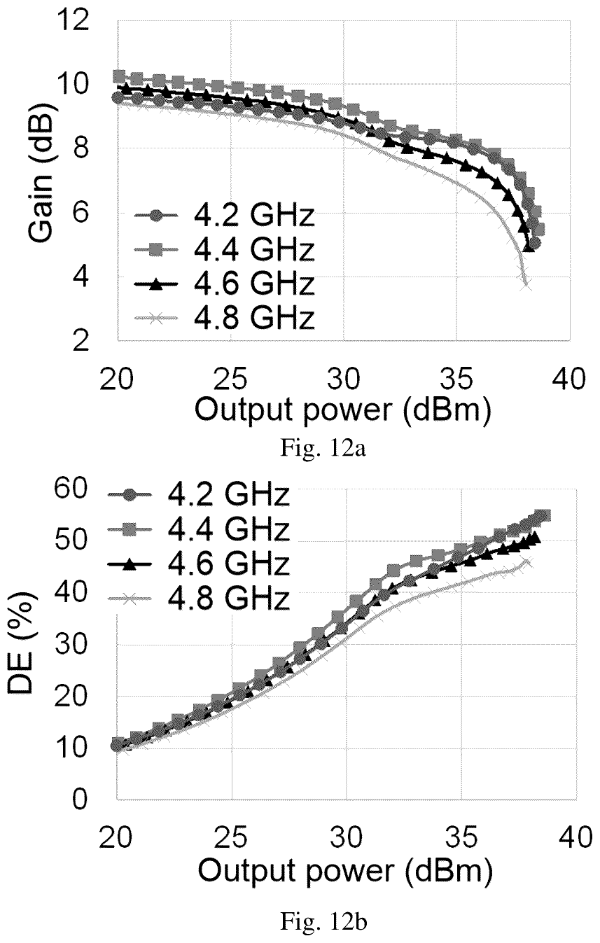

Large-signal performance of the fabricated sample DPA is shown in FIGS. 11a-11b and FIGS. 12a-12b. FIGS. 11a-11b show respectively the gain and DE versus output power for different peaking PA gate biasing at 4.3 GHZ. Since the peaking PA is more deeply biased into Class C from −4 V to −7 V, Pₛₐₜ is lower but higher output back-off (OBO) with Doherty behavior can be achieved. The peaking PA is finally biased with −5 V for the frequency range from 4.2 to 4.6 GHz. Doherty behavior is realized and the DPA exhibited higher than 47.5% DE at 6-dB OBO with Pₛₐₜ around 38 to 39 dBm from 4.2 to 4.6 GHZ, as shown in FIG. 12a. The gain compression at the back-off point and at saturation in FIG. 12b is less than 1.8 and 3.8 dB, respectively. Performance at 4.8 GHz is also shown for reference and can be further optimized by tuning the bondwire inductance.

Performance of the fabricated sample DPA is summarized and compared with other fully integrated GaN DPAs in Table I below. The fabricated sample DPA (indicated as “this work” in Table I) can achieve similar Pₛₐₜ and DE values at the OBO and Pₛₐₜ compared to other DPAs [3]-[8]. However, the gain is lower than those DPAs operating in lower frequency ranges [3], [8]. A 150-nm GaN process is used in this fabricated sample while others included in Table I used a 250-nm GaN process. There is a trend obtained between the gain and Pₛₐₜ by tuning the output impedance of the carrier and peaking PAs. The die size of the fabricated sample DPA is sub-1-mm² (0.99×0.85 mm²). This is at least four to ten times smaller than the size of the other DPAs in [3]-[8], which can significantly reduce GaN die costs. When the other DPAs with on-chip inductors used are assembled into a package, a clearance of 0.2 mm or more between the die edge and the second bond of the bondwires should be reserved for reliability. Therefore, this die with CSN and CLN in the fabricated sample DPA can be packaged with a small form-factor compared to the others shown in Table 1. The modulated large-signal performance is not included because the CSN and CLN architectures in the fabricated sample DPA will give similar linearity improvements compared to other DPAs after digital predistortion linearization used. Other bandwidth and efficiency enhancement techniques can be applied to improve the performance with larger the area.

TABLE I
COMPARISON WITH OTHER GAN DPAS

| Ref. | This work | [3] | [4] | [5] | [6] | [7] | [8] |
|---|---|---|---|---|---|---|---|
| Freq (GHz) | 4.2-4.6 | 2.6 | 5.1-5.9 | 4.5-5.2 | 4.5-6.0 | 6.1-6.8 | 4.1-5.6 |
| Pₛₐₜ (dBm) | 38-39 | 44 | 36-38.7 | 40.4-41.2 | 35-36 | 40.8-41.4 | 38.4-39.5 |
| Bandwidth (%) | 9.1 | — | 14.5 | 14.4 | 28.6 | 10.9 | 31 |
| DE@Pₛₐₜ (%) | 47.5-51.5 | — | 44-48 | 55-63 | 43-49 | 60-62 | 51.7-60.8 |
| DE @OBO (%) | 39-42 | 54.2 | 32-51 | 47-50 | 24-32 | 44-47 | 38.5-46.5 |
| OBO (dB) | 6 | 6 | 6 | 6 | 6 | 6 | 6 |
| Gain @OBO (%) | 8-8.2 | 13.7 | 14.4-17.3 | 8-11 | 7.6-11.6 | 9.6-10.5 | 8.3-11.2 |
| Die area | 0.99 × 0.85 | 2.6 × 1.8 | 2.5 × 1.6 | 2.2 × 2.1 | 3.0 × 2.8 | 2.8 × 1.5 | 2.6 × 3.0 |
| (mm × mm) | | | | | | | |
| Estimated | 2.7 × 2.4 | 3.0 × 2.2 | 2.9 × 2.0 | 2.6 × 2.5 | 3.4 × 3.2 | 3.2 × 1.9 | 3.0 × 3.4 |
| package area | | | | | | | |
| (mm × mm) | | | | | | | |
| Inductors used | Bondwire | Bondwire | On-chip | On-chip | On-chip | On-chip | On-chip |
| Process (nm) | 150 | 400 | 250 | 250 | 250 | 250 | 250 |

One can see from Table 1 that the fabricated sample DPA creates a small form-factor package. The CSN and CLN networks in the DPA reduce the overall die size to sub-1-mm², without degradation in performance compared to other DPAs. Further optimization of the input and OMNs within the CSN and CLN could achieve higher operating frequency within the sub-6-GHz 5G frequency band. DPAs according to embodiments of the invention is suitable for the realization of broadband and multi-standard small-cell base stations and is easy to incorporate into on-chip designs.

The exemplary embodiments described above in general disclose a GaN DPA occupying a sub-1-mm² die area. This small die with the CSN and the CLN can be fully packaged in a small form factor. Previous solutions have integrated all components into the die with complicated matching and bias networks, resulting in a large and expensive die area. Innovative component merging and compact bond-wire matching in the CSN and CLN have substantially reduced the die size for future massive MIMO small cells. An exemplary DPA was designed and fabricated using a commercial 150-nm GaN/SiC HEMT process to validate architecture and design methodologies. Experimental results demonstrate that this sub-1-mm2 DPA can deliver saturated powers (Psat) of 38-39 dBm from 4.2 to 4.6 GHz. Measured drain efficiencies (DEs) of the DPA are more than 45%, from the 6-dB back off power to Psat, over the entire frequency band. The shunt on-chip inductors in these high-pass networks are replaced by the bondwires that will normally be considered parasitic inductances in RF/microwave packaging.

The exemplary embodiments are thus fully described. Although the description referred to particular embodiments, it will be clear to one skilled in the art that the invention may be practiced with variation of these specific details. Hence this invention should not be construed as limited to the embodiments set forth herein.

While the embodiments have been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

It will be appreciated by persons skilled in the art that the expressions “network” or the like are used in the description to refer to a circuit or circuit part, which can be form by any combination of transmission line, transmission line portions, or other active or inactive electronic circuit components. The term “offset line” can also be called an “offset transmission line”. The term “main power amplification device”, “carrier device”, or the like, refers to a “carrier power amplifier” or “carrier amplifier”. The term “auxiliary power amplification device”, “peaking device”, or the like, refers to a “peaking power amplifier” or “peaking amplifier”. Unless otherwise specified, the term “connected”, “engaged”, “coupled with/to”, or the like, may refer to direct or indirect connections, engagement, coupling, etc. The expression “Doherty power amplifier circuit” can be used to refer to a “Doherty power amplifier” or any parts of it.

In FIG. 6, a specific bondwire-involved implementation of a DPA according to an embodiment of the invention is shown, but one skilled in the art should understand that the circuit in FIG. 6 is in no way meant to be limiting. The invention may be implemented in many other ways, and not necessarily by using bondwires for merged inductors as shown in FIG. 6. For example, the merged inductors may be implemented by other technologies. Rather, an important feature of the invention is the simplification of the circuit for the DPA by merging adjacent inductors as mentioned previously.

For the complete DPA circuit shown in FIG. 6, specific values/characteristics were disclosed for various capacitors, inductors, voltage supplies, and transistors. However, these specific values or characteristics are for an exemplary DPA only, and they should by no means interpreted as limiting the invention. Those skilled in the art will appreciate that different values of the components can be chosen, in particular for other DPA topologies, without departing from the spirit of the invention. The exemplary source and load networks in FIGS. 3-4 can also be applied to other DPA topologies to minimize circuit size.

What is claimed is:

1. A Doherty power amplifier comprising:
a) an input;
b) an output;
c) a main power amplification device connected between the input and the output;
d) an auxiliary power amplification device connected between the input and the output, and arranged in parallel with the main power amplification device;
e) an output matching network connected between the output, and the main and auxiliary power amplification devices; and
f) an impedance transformer connected between the output matching network and the output;
wherein a first part of the output matching network is merged with a first part of the impedance transformer.

2. The Doherty power amplifier of claim 1, wherein both the output matching network and the impedance transformer comprise high-pass x-type lumped networks; the first part of the output matching network and the first part of the impedance transformer comprising inductors that are merged.

3. The Doherty power amplifier of claim 2, wherein the inductors that are merged are implemented as a bondwire.

4. The Doherty power amplifier of claim 1, further comprises a power splitter and an input offset line that are connected between the input, and the main and auxiliary power amplification device; wherein a first part of the input offset line is merged with a first part of the power splitter.

5. The Doherty power amplifier of claim 4, wherein both the input offset line and the power splitter comprise high-pass x-type lumped networks; the first part of the input offset line and the first part of the power splitter comprising inductors that are merged.

6. The Doherty power amplifier of claim 5, wherein the inductors that are merged are implemented as a bondwire.

7. The Doherty power amplifier of claim 5, wherein the power splitter further comprises a second part that comprises inductors which are merged within the power splitter.

8. The Doherty power amplifier of claim 1, further comprises an input matching network that is connected between the input, and the main and auxiliary power amplification devices; the input matching network comprising shunt inductors which are implemented using bondwires.

9. The Doherty power amplifier of claim 8, wherein the input matching network is merged with an input bias network.

10. The Doherty power amplifier of claim 1, wherein the output matching network is merged with an output bias network.

11. The Doherty power amplifier of claim 1, wherein the impedance transformer further comprises a second part that comprises an inductor implemented using a bondwire.

12. The Doherty power amplifier of claim 1, wherein the impedance transformer is a λ/4 impedance transformer.

13. The Doherty power amplifier of claim 1, wherein the first part of the output matching network is further merged with a first part of an output offset line.

14. The Doherty power amplifier of claim 13, wherein a second part of the output matching network is merged with a second part of the output offset line.
